(19) United States
(12) Patent Application Publication
(10) Pub. No.: US 2021/0408378 A1
(43) Pub. Date: Dec. 30, 2021

(54) COATING PROCESS AND COATING APPARATUS USABLE FOR DEVICE FORMATION

(71) Applicants: KABUSHIKI KAISHA TOSHIBA, Tokyo (JP); TOSHIBA ENERGY SYSTEMS & SOLUTIONS CORPORATION, Kawasaki-shi (JP)

(72) Inventors: Katsuyuki NAITO, Bunkyo (JP); Naomi SHIDA, Minato (JP); Takashi KUMATA, Kawasaki (JP); Yutaka SAITA, Yokohama (JP)

(73) Assignees: KABUSHIKI KAISHA TOSHIBA, Tokyo (JP); TOSHIBA ENERGY SYSTEMS & SOLUTIONS CORPORATION, Kawasaki-shi (JP)

(21) Appl. No.: 17/469,278

(22) Filed: Sep. 8, 2021

Related U.S. Application Data
(63) Continuation of application No. PCT/JP2020/009220, filed on Mar. 4, 2020.

(51) Int. Cl. H01L 51/00; B05C 5/02; B05C 11/10; H01L 51/42

(52) U.S. Cl. CPC H01L 51/0003; B05C 5/025; H01L 51/4253; B05C 11/1002; B05C 11/1044; B05C 5/027

(57) ABSTRACT

The embodiment provides a coating process capable of simply and inexpensively producing devices having strip-shaped cells, and a coating apparatus usable for the process. The process comprises:
(a) placing a bar coating head almost parallel to the substrate,
(b) placing plural coating nozzles for supplying coating solution to meniscus-forming parts, so that the center between each adjacent two of the coating nozzles may correspond to the separation area between each adjacent two of the strip-shaped cell bases, and
(c) moving the substrate or the bar coating head while the coating solution is being supplied from the nozzles, to form the coating films.

### CROSS REFERENCE TO RELATED APPLICATIONS

This application is based upon and claims the benefit of priority from the prior International Patent Application No. PCT/JP2020/009220, filed on Mar. 4, 2020, the entire contents of which are incorporated herein by reference.

### FIELD

Embodiments of the present disclosure relate to a coating process and a coating apparatus which are usable for device formation.

### BACKGROUND

Organic thin-film solar cells and organic-inorganic hybrid solar cells, in which organic semiconductors are used, are expected as low-lost solar cells because their active layers can be formed by inexpensive coating processes. In order that organic thin-film solar cells or organic-inorganic hybrid solar cells can be realized at low cost, it is required to evenly lay coating materials for forming organic active layers and other layers. Although each layer has a thickness of several nanometers to several hundreds of nanometers, it is necessary to form such thin layers evenly in large areas. For example, meniscus coating method is known as a kind of roll-to-roll (R2R) coating method, which makes it possible to form a very thin layer in a large area by coating at low cost. A single large-area coating film can be obtained by a meniscus coating process in which the coating solution is supplied from plural nozzles to a bar coating head. This process is easily carried out with an apparatus of simple structure. However, it is often difficult to form a film of even thickness.

In a solar cell module, cells are connected in series to raise the voltage. Accordingly, it is general to form and then divide a large-area film by a scribing or lithographic technique so as to produce strip-shaped cells. The higher electroconductivity the base-electrode has, the wider the cells tend to be able to be made. The wider the separation areas among the cells is, the more easily the device can be produced but the smaller aperture ratio the resultant device has and hence the smaller output power the device tends to generate. It is therefore an important matter in device production to control the widths of the separation areas.

As compared with a lithographic process, a scribing one can be carried out more easily. However, a scribing process often generates residues, which may cause defects of the device. In addition, a scribing process with a laser beam needs large energy while one with a physical blade often suffers from working lifetime of the blade.

In a scribing process, the position to be scribed needs to be accurately controlled in accordance with the base-electrode. However, the base-electrode is covered with a film formed thereon, and hence is often difficult to recognize.

For forming plural strip-shaped cells arranged in parallel, it is studied to adopt a meniscus coating process in place of the scribing process. Specifically, the process starts with preparing a bar coating head provided with discrete parts having widths corresponding to the cell widths to be formed. While the coating solution is supplied individually to the discrete parts from plural nozzles, the coating is carried out. This coating process makes it possible to form separated cells having widths of individually corresponding parts. However, there is a problem in that the bar coating head has such a complex structure as to increase the cost and the frequency of cleaning the head.

### BRIEF DESCRIPTION OF THE DRAWINGS

FIG. 1 is a schematic sketch illustrating a coating process according to the embodiment;

FIG. 2 shows a schematic sectional view illustrating a coating apparatus according to the embodiment.

### DETAILED DESCRIPTION

The coating process according to the embodiment is a coating process for forming coating films by meniscus coating on strip-shaped cell bases arranged on a substrate, comprises:

(a) placing a bar coating head almost parallel to said substrate,

(b) placing plural coating nozzles for supplying coating solution to parts where meniscuses are formed, so that the center between each adjacent two of said coating nozzles may correspond to the separation area between each adjacent two of said strip-shaped cell bases, and

(c) moving said substrate or said bar coating head while said coating solution is being supplied from said nozzles, to form said coating films.

Also, the coating apparatus according to the embodiment is a coating apparatus for forming coating films by meniscus coating on strip-shaped cell bases arranged on a substrate; and comprises

a bar coating head placed almost parallel to said substrate,

a member for carrying said substrate,

plural coating nozzles for supplying coating solution,

a member for supplying said coating solution to said coating nozzles, and

a member with which said coating nozzles are so placed that the center between each adjacent two of said coating nozzles may correspond to the separation area between each adjacent two of said strip-shaped cell bases.

The embodiments will be explained with reference to the attached drawings.

In the explanation of the embodiments, common members or components are denoted by the same reference numerals and the description thereof is not repeated herein. In addition, the drawings are schematic views for promoting understanding of the embodiments. Accordingly, even if the shapes, dimensions, proportions and the like of the members or components may be different from those of the real apparatus, the designs thereof can be appropriately changed in consideration of the following description and known techniques.

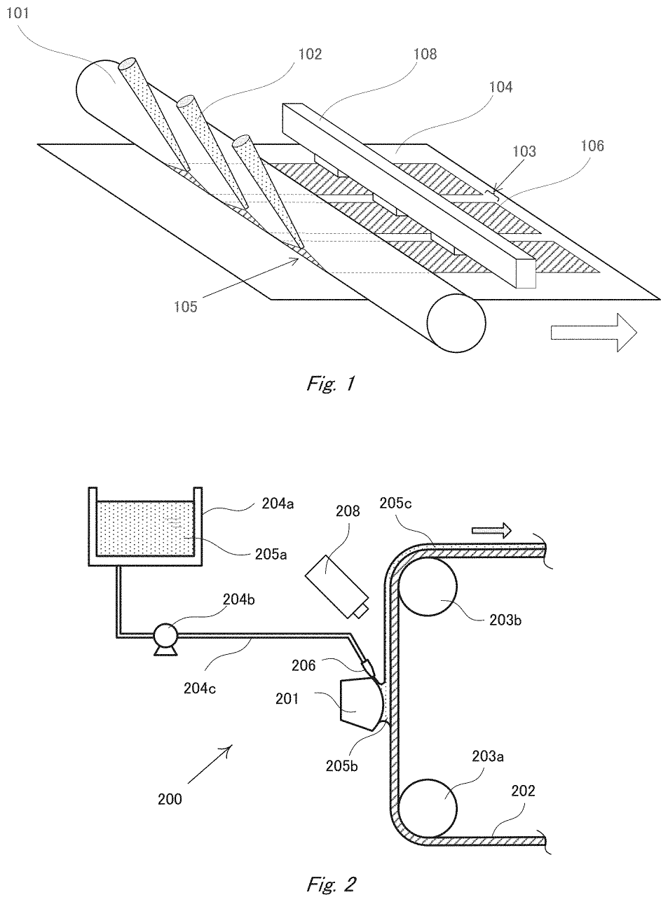

FIG. 1 schematically illustrates a coating process according to the embodiment. In FIG. 1, a bar coating head 101 is supplied with coating solution 105 from plural coating nozzles 102. The coating solution flows into gaps between the bar coating head 101 and a substrate 104, to form meniscuses near the gaps. The bar coating head 101 is placed almost parallel to the substrate 104, so that the gaps are almost the same. While the coating solution 105 is being continuously suppled, the substrate 104 is conveyed in the direction of the arrow so that it moves relative to the bar coating head 101. As a result, coating films 106 (often referred as “thin films”) are formed. Although the substrate is moved in this case, the bar coating head may be moved. The moving direction is preferably almost perpendicular to the longitudinal direction of the bar coating head.

On the substrate, cell bases (such as transparent electrodes or the like) are beforehand formed. In order to adjust relative positions of the nizzles and the substrate, the surface of the substrate before coating is observed with an optical instrument 108, with which the positions of the nozzles may be observed at the same time. The optical instrument measures the reflectance or transmittance distribution of the substrate. On the basis of the measured results, the plural coating nozzles can be so placed that the center between each adjacent two of the coating nozzles may correspond to the separation area between each adjacent two of the cell bases.

Here, it should be noted that the “cell” in the embodiment does not necessarily mean a battery cell but generally means a multilayer device formed in a small section. Accordingly, the “cell base” means a part of the multilayer “cell” structure.

Further, the terms “almost parallel” and “almost perpendicular” in the embodiment mean that slight differences from strict parallelism and perpendicularity, respectively, are allowable as long as the effect of the embodiment is not impaired. Specifically, for example, in the above case, the substrate 102 moves relative to the bar coating head 101 in the direction typically perpendicular, namely, at an angle of 90° to the longitudinal direction of the bar coating head, but the direction may be inclined at an angle within about ±15°. Accordingly, the term “almost parallel” or “almost perpendicular” means parallel or perpendicular with an allowable margin of about ±15°, respectively.

The substrate can be freely selected from those generally used for electronic devices and the like. For example, the substrate is made of inorganic materials, such as glass and silicon; or organic materials, such as polyethylene terephthalate (hereinafter, referred to as “PET”), polyethylene naphthalate (hereinafter, referred to as “PEN”), polycarbonate (hereinafter, referred to as “PC”) and polymethylmethacrylate (hereinafter, referred to as “PMMA”). Preferred are flexible organic materials because they make R2R coating easy.

As the bar coating head 101, a rod-shaped one is generally employed. If the bar coating head 101 is cut perpendicularly to the longitudinal direction at the parts where meniscuses are formed, the formed cross section is preferably the same at any cutting position in the longitudinal direction. This means that, in a section parallel to the longitudinal direction, the surfaces on which meniscuses are formed preferably show straight sectional lines. The sectional lines given by the surfaces on which meniscuses are formed are kept at a constant distance from the substrate 104. Meanwhile, in the bar coating head, the surfaces on which meniscuses are not formed, for example, the back surfaces opposite to the coating surfaces, may be in any shape.

In the embodiment, the bar coating head can have cross sections in various shapes, such as, circles, ellipses and trapezoids. Typically, the bar coating head is in the shape of a constant-width board or column. As an example, FIG. 1 shows a columnar bar coating head. The bar coating head may have a sectional shape outlined by an arc at the bottom and three straight line segments at the top and both sides.

Plural coating nozzles (hereinafter, often simply referred as “nozzles”) 102 are arranged and each of them individually supplies the coating solution to form a coating film. In FIG. 1, the coating solution suppled individually from each nozzle forms each separated coating film 106, which individually corresponds to each strip-shaped thin film to be produced.

The nozzles are so placed that the center between each adjacent two of the nozzles may correspond to the separation area between each adjacent two of the cell bases. The separation area is normally a constant-width belt-shaped region. In the embodiment, the center between adjacent two of the nozzles is regarded to correspond to the separation area when the center of the separation area is located at the position of the center between the two adjacent nozzles with an allowable margin of +10%, preferably ±5% based on the distance between the two nozzles.

The plural strip-shaped thin films are arranged according to the designed structure of the aimed device such as a solar cell. In the coating process according to the embodiment, the coating solution is supplied and spread onto the head parts where meniscuses are formed, to keep the shapes of meniscuses. However, according to the conditions, it is possible not to form the coating film at all or to form the coating film in a thin thickness or conversely in a thick thickness in the area corresponding to the center between each adjacent nozzles, namely, on each separation area. FIG. 1 shows an example in which adjacent coating films 106 are separated from each other and hence they can be directly adopted as the strip-shaped thin films. However, under some conditions, adjacent two coating films may be connected. In that case, the film thickness in the separation area can be made thin or thick by controlling, for example, positions of the nozzles, coating speed and/or properties of the coating solution. Since the coating films thus formed are continuously connected, it is difficult to directly obtain the plural strip-shaped thin films. Accordingly, in order to obtain the plural strip-shaped thin films, the coating film formed on the separation area is partly or completely removed, for example, by scribing. In this process, the parts having different film thicknesses can be removed by scribing and thereby those having uniform film thicknesses can be used as the strip-shaped thin films. The process, therefore, can reduce property variation among the cells corresponding to the individual thin films. It should be noted that, if the film on the separation area is made to have a thickness different from that on the peripheral area, it is easy to optically recognize the areas. Consequently, for example, when the formed coating films or thin films are further coated with overlying coating films or when the separation area is subjected to scribing, it becomes easy to match the positions.

In the embodiment, the coating solution may begin to be supplied either before or after the substrate or the bar coating head begins to move. Properties of the coating films can be changed by changing when the coating solution begins to be supplied.

If the coating solution begins to be supplied to form meniscuses in the gaps between the substrate and the bar coating head before the substrate or the bar coating head begins to move, the coating solution supplied thereafter forms meniscuses less spreading. That is because the spread of the meniscuses is reduced by the surface tension of the underlying spread formed from the coating solution previously supplied. Accordingly, the coating solution is laid on some areas in a smaller amount than on the peripheral areas. As a result, the coating film on the separation area or the peripheral areas thereof (areas near to both terminal edges of each coating film) is likely to be thin. This is preferred because the thin film is easily subjected to treatments such as scribing and generates residues in a small amount.

In contrast, if the coating solution is supplied to the gaps between the substrate and the bar coating head so as to form meniscuses for coating after the substrate or the bar coating head begins to move, the coating film on the separation area or the peripheral areas thereof is likely to be thick. The thick coating film is easy to recognize optically, and accordingly it is easy to match the positions when the film is subjected to scribing. If the coating film is too thin to optically recognize, it is preferred to thicken the film on the separation area.

The array pitch of the nozzles is preferably an integer multiple of that of the strip-shaped cell bases. In order to perform scribing under constant conditions, both array pitches are preferably the same. The pitch of the nozzles is preferably adjusted in consideration of properties (such as, surface tension and viscosity) of the coating solution. The solution having large surface tension and small viscosity forms meniscuses so rapidly spreading that homogeneous coating films can be easily obtained even if the nozzles are arrayed with a large pitch. The meniscus spreading speed is almost in proportion to the square root of the ratio of the surface tension to the viscosity. On the basis of that, the calibration curve is plotted by use of coating solutions having known surface tensions and viscosities, and thereby the optimal intervals among the nozzles are preferably determined and adopted when the coating speed is changed.

If the array pitch of the nozzles is larger than that of the cell bases, the number of scribing repetitions can be reduced although it is necessary to change the scribing conditions. The coating films are arranged preferably with a wide pitch, and hence the array pitch of the nozzles is preferably one to three time as large as that of the cell bases.

The intervals among the nozzles can be adjusted by various methods. For example, spacers are placed among the plural nozzles to control the intervals. This method can easily adjust the intervals if various sizes of spacers are prepared, and further makes it possible to carry out the coating with the nozzles arranged at plural different intervals.

The nozzles may be fixed with a fixing member provided with plural holes or grooves arranged at a constant interval. This method can easily fix the nozzles with high accuracy if the nozzles have needle shapes.

Further, the nozzles may be fixed with an expandable and compressible member having a pantograph mechanism in a manner where they are attached on the terminal ends or joint parts of the member. In this method, the intervals among the nozzles can be easily changed by expanding or compressing the member.

In the present embodiment, the coating procedure can be carried out in any of the following manners:

(i) the substrate is moved with the bar coating head fixed,

(ii) the bar coating head is moved with the substrate fixed, or

(iii) the substrate and the bar coating head are both moved.

If the substrate to be coated is flexible or in a long belt shape, it is preferred in view of stability that (i) the substrate be moved with the bar coating head fixed. Particularly when the coating films are intended to be formed on the substrate made of resin or the like, it is preferred to adopt what is called a roll-to-coat system, in which the substrate before coating is wound in a roll shape and then the coated substrate is rewound up in another roll.

The coating process described above can be adopted to form thin films for cells. Those thin films are employed for a device comprising, as component elements, strip-shaped cells arranged on the substrate.

FIG. 2 is a schematic sectional view illustrating a coating apparatus usable for producing a device according to the embodiment.

A coating apparatus 200 is a coating apparatus for forming coating films by meniscus coating on strip-shaped cell bases arranged on a substrate; and comprises

a bar coating head 201 placed almost parallel to the substrate,

a member (203a and 203b) for carrying the substrate 202,

plural coating nozzles 206 (one of which is shown in FIG. 2) for supplying coating solution 205a, and

a member (204a, 204b and 204c) for supplying the coating solution to the coating nozzles. The plural nozzles supply the coating solution to parts where meniscuses are formed. The nozzles are so placed that the center between each adjacent two of the nozzles may correspond to the separation area between each adjacent two of the cell bases. The members 207a and 207b are optical instruments for observing positions on the substrate surface and positions of the nozzles, respectively. The substrate and the nozzles are observed with the optical instruments to measure the reflectance or transmittance of the substrate and the positions of the nozzles, respectively, and thereby it becomes possible to detect the positions of the separation areas and also to adjust the nozzle positions in accordance with the detected positions of the separation areas.

In the coating apparatus, the coated substrate is normally directly carried into a dryer unit (not shown), where a coating film 205c is dried.

The bar coating head shown in FIG. 2 is a rod-shaped member having one curved surface on which meniscuses are formed and the other three smooth surfaces.

The member 203a and 203b for carrying the substrate is, for example, a pair of rollers, one of which may be power driven to convey the substrate. Otherwise, the coated substrate may be wound around a power-driven axis. In that case, the power-driven axis is the member for carrying the substrate.

In the coating apparatus of the embodiment, the plural nozzles can be individually detachable.

The coating apparatus according to the embodiment can further comprise a member with which the intervals among the nozzles are controlled according to the viscosity and surface tension of the coating solution. As described above, the coating apparatus is preferably equipped with a member with which the nozzle intervals are adjusted to those optimally determined according to the surface tension and viscosity of the adopted coating solution on the bases of data obtained from coating solutions having known surface tensions and viscosities.

Examples of that member include: spacers placed among the nozzles to control the intervals thereof, a member provided with plural holes or grooves in which the nozzles are fixed, and an expandable and compressible member having a pantograph mechanism in which the nozzles are fixed on the terminal ends or joint parts so that the nozzle intervals can be controlled by expanding or compressing.

The coating apparatus of the embodiment comprises a member for supplying the coating solution to the nozzles. In FIG. 2, this member is constituted with a coating solution tank 204a, a solution feeding pump 204b, and a plumbing tube 204c. The tube 204c, which supplies the solution to the nozzles 206 in the coating apparatus of the embodiment, can be equipped with a joint at which the nozzle can be attached or detached. This joint makes it easy to attach or detach each nozzle onto or from the tube, respectively. The coating apparatus may include multiple pumps. In the example, the number of the multiple nozzles is equal with the number of the pumps. The number of the pumps can be reduced thereby. It is more favorable for the number of the nozzles to which the liquid 84 coating solution 205a is supplied from one pump to be 2ⁿ (n being an integer).

The coating apparatus of the embodiment can be provided with tubes individually connecting the nozzles to a single tank. This structure can simplify the plumbing system, and further it becomes easy to evenly control the supply from the tank to each nozzle at a constant amount by applying even pressure.

In the coating apparatus according to the embodiment, there are no particular restrictions on the moving direction of the substrate or the bar coating head. However, as shown in FIG. 2, the substrate is preferably coated while conveyed vertically from bottom to top with the bar coating head fixed. Since the substrate moves vertically from bottom to top, gravity is applied to the meniscus part and consequently a homogeneous film tends to be formed even with a high coating speed. However, in accordance with the constitution of the apparatus or properties of the coating solution, the moving direction can be adjusted and is generally within ±30° of the vertical direction.

The member for carrying the substrate preferably conveys the substrate from bottom to top, and the nozzles supply the coating solution preferably from above the parts where meniscuses are formed. That is because gravity is applied to the meniscuses and thereby it becomes possible to coat the substrate more rapidly. In addition, since the coating solution is supplied from above the parts where meniscuses are formed, there is also an effect of preventing dripping down.

The coating apparatus can be further provided with a member with which the distance between the bar coating head and the substrate is measured and controlled. This member can enhance the evenness of the coating film thickness.

The coating apparatus can be furthermore provided with a member with which the bar coating head is washed. The bar coating head can be regularly washed with the member so as to remove impurities coming from the atmosphere or solids deposited from the coating solution. For example, the member sprays or emits a solvent such as water, or applies ultrasonic waves.

The coating apparatus can be still further provided with a member with which a surplus of the coating solution is recovered. This member can prevent the coating solution from flowing backward after the coating procedure, can avoid loss of the expensive coating solution and can suppress emission of the solvent or the like to the environment.

In a process for producing a device comprising, as component elements, strip-shaped cells arranged on the substrate, the coating apparatus described above can be used for forming thin films constituting the cells.

### Example 1

The coating apparatus 200 shown in FIG. 2 is employed to form thin films for solar cells by coating in the following manner. The process begins with producing a transparent electrode on a rolled 300-mm wide PET film with a R2R compatible sputtering apparatus. The transparent electrode is made of ITO/Ag alloy/ITO and has a sheet resistance of 5 Ω/square. Subsequently, the transparent electrode is subjected to patterning by laser scribing to form strip-shaped electrodes separated by 50 μm-wide separation areas with a 20 mm cell pitch. Meanwhile, a bar coating head is produced. The bar coating head is made of SUS303, and has a circular cross-section with a radius of 10 mm and a length of 300 mm in the coating width direction.

On a 320 mm-long nozzle-fixing member provided with holes arranged with a pitch of 20 mm, 50 mm-long stainless steel-made needle nozzles with locking bases are fixed by fitting each nozzle into each hole. Each needle nozzle and a Teflon-made tube are connected with a detachable joint, so that the coating solution can be individually supplied with small pumps.

As a coting solution for forming hole transport layers, an aqueous dispersion of PEDOT/PSS is prepared. The solution is then laid on the above transparent electrodes on the PET film by use of the coating apparatus shown in FIG. 2. The bar coating head is so placed with an actuator that the minimum gap between the head and the PET substrate may be 150 μm. Further, the PET film, the bar coating head and the nozzles are observed with an optical instrument and positioned so that the center between each adjacent two of the nozzles may correspond to the separation area between each adjacent two of the transparent electrodes.

Before the substrate starts to be conveyed, 20 μL of the coating solution is supplied from each nozzle to the bar coating head so as to form meniscuses. While the angles of the nozzles and the gap distances are being controlled, the coating solution is continuously supplied with the PET substrate moved to obtain a coating film. The moving speed of the PET substrate is kept constant at 83 mm/second. The coated PET substrate is conveyed into a R2R compatible hot air drying furnace and continuously dried.

Thereafter, in order to prepare a coating solution for forming organic active layers of solar cells, 8 mg of PTB7 ([Poly{4,8-bis[(2-ethylhexyl)oxy]-benzo[1,2-b:4,5-b′]dithiophene-2,6-diyl-1t-alt-3-fluoro-2-[(2-ethylhexyl)carbonyl]thieno[3,4-b]thiophene-4,6-diyl}]/p-type semiconductor) and 12 mg of PC70BM ([6,6]-phenyl-C71-butyric acid methyl ester/n-type semi-conductor) are dispersed in 1 mL of monochlorobenzene. The solution is then laid on the PET film provided with the hole transport layer formed thereon by use of the coating apparatus shown in FIG. 2. The bar coating head is so placed with an actuator that the minimum gap between the head and the substrate surface may be 300 μm. In the same manner as described above, the PET film, the bar coating head and the nozzles are positioned so that the center between each adjacent two of the nozzles may correspond to the separation area between adjacent two of the transparent electrodes. Before the substrate is moved, 40 μL of the coating solution is supplied from each needle nozzle so as to form meniscuses. While the angles of the nozzles and the gap distances are being controlled, the coating solution is continuously supplied with the PET substrate moved to obtain a coating film. The moving speed of the PET substrate is kept constant at 83 mm/second. The coated PET substrate is conveyed into a R2R compatible hot air drying furnace and continuously dried. Both of the coating films formed in the above manner are thinner in the separation areas than in the peripheral areas thereof. Accordingly, it is easy to remove the films in the separation areas by ascribing, so that the coating films are divided at the separation areas. Thus, they are convenient for producing strip-shaped cells.

### Example 2

In the present example, organic active layers used for semitransparent solar cells are produced. The procedure of Example 1 is repeated except that the coating solution for forming organic active layers is half the concentration of the solution in Example 1, that the meniscuses are not formed before the substrate starts to be conveyed, and that the nozzles start to supply the coating solution at the same time as the substrate starts to be conveyed. Both of the formed coating films are thicker in the separation areas than in the peripheral areas thereof. Accordingly, it is easy to recognize the separation areas with the optical instrument and hence the films in the separation areas are easily removed by ascribing. The thick film parts in the separation areas are thus removed, and thereby it becomes possible to reduce the deviation in properties of divided coating films.

### Example 3

The process begins with producing a transparent electrode on a rolled 300-mm wide PET film with a R2R compatible sputtering apparatus. The transparent electrode is made of ITO/Ag alloy/ITO and has a sheet resistance of 10 Ω/square. Subsequently, the transparent electrode is subjected to patterning by laser scribing to form strip-shaped electrodes separated by 50 μm-wide separation areas with a 12 mm cell pitch. Meanwhile, a rod-shaped bar coating head is produced. The bar coating head is made of SUS303, and has an almost trapezoidal cross section having an arc base with a curvature radius of 80 mm and a length of 300 mm in the coating width direction.

On a 320 mm-long nozzle-fixing member provided with holes arranged with a pitch of 24 mm, 50 mm-long stainless steel-made needle nozzles with locking bases are fixed by fitting each nozzle into each hole. Each needle nozzle and a Teflon-made tube are connected with a detachable joint, so that the coating solution can be individually supplied with small pumps.

As a coting solution for forming hole transport layers, an aqueous dispersion of PEDOT/PSS is prepared. The solution is then laid on the above transparent electrodes on the PET film by use of the coating apparatus shown in FIG. 2. The bar coating head is so placed with an actuator that the minimum gap between the head and the PET substrate may be 150 μm. Further, the PET film, the bar coating head and the nozzles are positioned so that the center between each adjacent two of the nozzles may correspond to the separation area between each adjacent two of the transparent electrodes.

Before the substrate starts to be conveyed, 25 μL of the coating solution is supplied from each nozzle to the bar coating head so as to form meniscuses. While the angles of the nozzles and the gap distances are being controlled, the coating solution is continuously supplied with the PET substrate moved to obtain a coating film. The moving speed of the PET substrate is kept constant at 83 mm/second. The coated PET substrate is conveyed into a R2R compatible hot air drying furnace and continuously dried.

Thereafter, in order to prepare a coating solution for forming organic active layers of solar cells, 8 mg of PTB7 ([Poly{4,8-bis[(2-ethylhexyl)oxy]-benzo[1,2-b:4,5-b′]dithiophene-2,6-diyl-1t-alt-3-fluoro-2-[(2-ethylhexyl)carbonyl]thieno[3,4-b]thiophene-4,6-diyl}]/p-type semiconductor) and 12 mg of PC70BM ([6,6]-phenyl-C71-butyric acid methyl ester/n-type semi-conductor) are dispersed in 1 mL of monochlorobenzene. The solution is then laid on the PET film provided with the hole transport layer formed thereon by use of the coating apparatus shown in FIG. 2. The bar coating head is so placed with an actuator that the minimum gap between the head and the substrate surface may be 300 μm. In the same manner as described above, the PET film, the bar coating head and the nozzles are positioned so that the center between each adjacent two of the nozzles may correspond to the separation area between each adjacent two of the transparent electrodes. Before the substrate starts to be conveyed, 45 μL of the coating solution is supplied from each needle nozzle so as to form meniscuses. While the angles of the nozzles and the gap distances are being controlled, the coating solution is continuously supplied with the PET substrate moved to obtain a coating film. The moving speed of the PET substrate is kept constant at 83 mm/second. The coated PET substrate is conveyed into a R2R compatible hot air drying furnace and continuously dried. The coating films thus formed are thinner in the separation areas than in the peripheral areas thereof. Accordingly, it is easy to remove the films in the separation areas by scribing, so that the coating films are divided at the separation areas. Thus, they are convenient for producing strip-shaped cells.

While certain embodiments have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fail within the scope and sprit of the invention.

1. A coating process for forming coating films by meniscus coating on strip-shaped cell bases arranged on a substrate, comprising:
(a) placing a bar coating head almost parallel to said substrate,
(b) placing plural coating nozzles for supplying coating solution to parts where meniscuses are formed, so that the center between each adjacent two of said coating nozzles may correspond to the separation area between each adjacent two of said strip-shaped cell bases, and
(c) moving said substrate or said bar coating head while said coating solution is being supplied from said nozzles, to form said coating films.

2. The process according to claim 1, wherein said parts where meniscuses are formed are gaps between said bar coating head and said substrate.

3. The process according to claim 1, wherein first said coating solution begins to be supplied to form meniscuses on said gaps and thereafter said substrate or said bar coating head begins to be moved.

4. The process according to claim 1, wherein the solution forming meniscuses on said separation areas is in a smaller amount than that on the peripheral areas thereof.

5. The process according to claim 1, wherein the array pitch of said nozzles is the same as that of said cell bases.

6. The process according to claim 1, wherein the intervals among said nozzles are controlled on the basis of the viscosity and surface tension of said coating solution.

7. The process according to claim 1, wherein said substrate is moved with said bar coating head fixed.

8. The process according to claim 1, wherein said substrate before coating is wound in a roll shape and then the coated substrate is rewound up in another roll.

9. The process according to claim 1, wherein the reflectance or transmittance distribution of said substrate, on which said strip-shaped cell bases are arranged, is measured and thereby the plural coating nozzles are so placed that the center between each adjacent two of the coating nozzles may correspond to the separation area between each adjacent two of the cell bases.

10. The process according to claim 1, wherein the coating films formed on the separation areas are partly or completely treated by scribing to form strip-shaped thin films.

11. A coating apparatus for forming coating films by meniscus coating on strip-shaped cell bases arranged on a substrate;
comprising
a bar coating head placed almost parallel to said substrate,
a member for carrying said substrate,
plural coating nozzles for supplying coating solution,
a member for supplying said coating solution to said coating nozzles, and
a member with which said coating nozzles are so placed that the center between each adjacent two of said coating nozzles may correspond to the separation area between each adjacent two of said strip-shaped cell bases.

12. The apparatus according to claim 11, wherein said bar coating head shows the same cross section, which is perpendicular to the longitudinal direction, in the longitudinal direction within the parts where meniscuses are formed.

13. The apparatus according to claim 11, wherein said coating nozzles are individually detachable.

14. The apparatus according to any of claim 11, further comprising a member with which the intervals among said nozzles are adjusted on the basis of the viscosity and surface tension of said coating solution.

15. The apparatus according to claim 11, furthermore comprising spacers placed among the nozzles to control the intervals thereof.

16. The apparatus according to claim 11, still further comprising a nozzle-fixing member provided with plural holes or grooves arranged at a constant interval.

17. The apparatus according to claim 11, wherein said coating nozzles are fixed on the terminal ends or joint parts of an expandable and compressible member having a pantograph mechanism.

18. The apparatus according to claim 11, wherein said coating nozzles have joints with which they can be detachably connected to tubes supplying said coating solution.

19. The apparatus according to claim 11, yet further comprising tubes which connect a single coating solution tank and said plural coating nozzles.

20. The apparatus according to claim 11, yet furthermore comprising a member for measuring reflectance or transmittance distribution of said substrate.
